(19) United States
(12) Patent Application Publication
(10) Pub. No.: US 2007/0120586 A1
(43) Pub. Date: May 31, 2007

(54) Phase-locked loop

(76) Inventor: Alexander Tyulpanov, Togliatti (RU)

Correspondence Address: MCGRATH, GEISSLER, OLDS & RICHARDSON, PLLC, P.O. BOX 1364, FAIRFAX, VA, 22038-1364, US

(21) Appl. No.: 11/603,992

(22) Filed: Nov. 24, 2006

(30) Foreign Application Priority Data
Nov. 24, 2005 (DE) DE 102005056033.4

(51) Int. Cl. H03L 7/06; B60C 23/00; H04L 27/00

(52) U.S. Cl. 327/157; 375/326; 340/447

(57) ABSTRACT

A phase-locked loop with reduced settling time, in particular in or for a transceiver circuit of a tire pressure monitoring system, is disclosed, The phase-locked loop includes, sequentially arranged in a signal path, phase comparators for generating a phase difference signal by comparing a reference input signal and an output signal, loop filters for filtering the phase difference signal, and an oscillator controlled by the filtered phase difference signal for generating the output signal. The phase-locked loop has an adapting circuit for reducing the settling time at switch-on of the phase-locked loop, which adapting circuit correlates the actual switch-on of the phase-locked loop with the signal behavior of the reference input signal. A transceiver circuit of a tire pressure monitoring system is also disclosed.

This nonprovisional application claims priority under 35 U.S.C. § 119(a) on German Patent Application No. DE 102005056033, which was filed in Germany on Nov. 24, 2005, and which is herein incorporated by reference.

### BACKGROUND OF THE INVENTION

1. Field of the Invention

The present invention relates to a phase-locked loop, in particular in or for a transceiver circuit of a tire pressure monitoring system, having sequentially arranged phase comparators for generating a phase difference signal from a reference input signal and an output signal, loop filters for filtering the phase difference signal, and an oscillator controlled by the filtered phase difference signal for generating the output signal. The invention further relates to a transceiver circuit of a tire pressure monitoring system.

2. Description of the Background Art

Phase-locked loops (PLL) have wide application in electronics, and are used to generate and synchronize clock signals, for example clock signals in microelectronic circuits. Such phase-locked loops are generally known in a variety of different design forms and variants. Strictly with regard to the basic structure of a phase-locked loop and its principle of operation, reference is made to Halbleiterschaltungselektronik (semiconductor circuit electronics), by Tietze, Schenk, 11th expanded edition, Springer Verlag, 1999, in particular FIG. 24.20.

FIG. 8 shows such a conventional phase-locked loop. A phase-locked loop 1 typically contains a phase detector 2, a loop filter 3 and an oscillator 4 in series, as well as a feedback path in which is arranged a divider 5. The phase-locked loop 1 also has a switch-on input 6 into which an enable signal XEN or a reset signal can be coupled to switch on or reset the phase-locked loop 1. A phase-locked loop 1 is a control circuit by which the oscillator 4 is synchronized with the phase of an input signal. When a phase and/or frequency difference occurs between the input signal XREF and the output signal XVCO of the phase-locked loop 1, the phase detector 2 generates a detector signal XDIFF with which the oscillator 4 that follows is adjusted until the phases and/or frequencies are synchronized again. In the synchronized state, the frequencies are equal and the phase difference between the input signal and the oscillator output signal is 0 or 90°. The phase-locked loop here is said to be locked in.

In the event of a phase difference between the input signal and output signal, the phase detector generates voltage pulses whose length reflects the particular detected phase difference. These voltage pulses drive the charge pump that is typically located in the phase detector and that, as a function of the signals present at the phase detector and the sign of the phase difference, adds a pulsed proportional current to the reference current of the current-controlled oscillator or subtracts it therefrom. The oscillator, to which the reference current is supplied in order to set its operating point, generates the frequency-modulated PLL output signal therefrom. As a result of the superposition of the pulsed proportional current on the oscillator's reference current, the pulse-width output frequency of the oscillator is altered; it is then fed back into the input of the phase detector as a feedback signal and thus as a controlled variable.

Phase-locked loops are, in particular, used in LF and HF data communications systems to generate low-frequency and high-frequency signals. When the phase-locked loop is switched on, the phase-locked loop requires a certain amount of time on account of settling processes before it is locked in. This time is hereinafter referred to as settling time or lock-in time. The same is true when the phase-locked loop is reset by a reset signal, for example a reset. However, the settling time cannot be used for data communication, so there is a need to keep this as short as possible. In conventional PLL circuits, the settling time in the case of a LF signal of 125 KHz is approximately 1 ms.

The settling time depends primarily on the phase error Δφ at the output of the phase detector 2. The following relationship results for the phase error Δφ:
Δφ=φ_{REF}−φ_{VCO} (1).
When
φ_{REF}=∫ω_{REF}dt (2)
φ_{VCO}=∫ω_{VCO}dt−φ₀ (3),
then
Δφ=∫ω_{REF}dt−∫ω_{VCO}dt−φ₀ (4).
Making the approximation
   φ_{REF}≈φ_{VCO} (5),
   then
   Δφ≈φ₀ (6).

φ_{REF} designates the phase of the reference signal XREF. φ_{VCO} designates the phase of the output signal XVCO, hence the signal at the output of the oscillator. ω_{REF} and ω_{VCO} designate the corresponding complex frequencies of these signals. φ₀ designates what is called the starting phase, hence the phase exhibited by the reference signal XREF when the phase-locked loop is switched on or reset.

The above relationship during a settling process of a prior art phase-locked loop will be described with reference to the diagrams of signal vs. time in FIG. 9.

Following a reset or switch-on of the phase-locked loop 1, the phase detector 2, the oscillator 4 and the divider 5 are reset and thus switched on, and start to operate. Since the reference signal XREF, in contrast, is independent of the resetting of the phase-locked loop 1, an initial phase φ₀ is defined with reference to a signal transition of this reference signal XREF and the switch-on of the PLL circuit 1. According to the above equations, this initial phase φ₀ corresponds approximately to the phase error Δφ. Depending on the point in time when the signal transition of the reference signal XREF takes place relative to the reset or switch-on of the PLL circuit 1, the result is a larger or smaller initial phase φ₀ and thus a correspondingly larger or smaller phase error Δφ.

Phase-locked loops are also used, in particular, in transceiver circuits of tire pressure monitoring systems. Modern tire pressure monitoring systems have a transponder as a transceiver, which is located, for example, on a rim of a tire. This transponder can be brought into a data communications connection with a transceiver circuit on the vehicle body. In order to then determine the tire pressure or other tire-specific parameters during operation of the motor vehicle, which is to say during travel, the fact that the transponder rotates with the tire, means that a relatively short time is thus available during which data communication between the transponder in the tire and the transceiver in the wheel well can be established and the data communication to exchange the tire-specific parameters can be carried out. In the case of very high speeds (for example, 300 km/h), the time window for this data communication is only approximately 2 ms. Within this time window, the transponder must be supplied with power, the phase-locked loop must be locked in to the nominal frequency, and the actual data communication to transmit the tire-pressure-specific parameters must then be carried out. Now if, as in the example described above, the settling time of the phase-locked loop is relatively long, then a relatively short period of time is available for the actual data communication, which is insufficient for proper data communication in many applications. Thus, particularly in such situations, the tire pressure monitoring system is no longer functional. This is a state of affairs that must be avoided as far as possible, especially since the need for measuring and monitoring tire-specific parameters is greatest in the aforementioned situations (in the case of high speed).

### SUMMARY OF THE INVENTION

It is therefore an object of the present invention to reduce the settling time of a phase-locked loop.

Accordingly, provision is made for a phase-locked loop (PLL) with a reduced settling time, in particular in or for a transceiver circuit of a tire pressure monitoring system, having, sequentially arranged in a signal path, phase comparators for generating a phase difference signal from comparison of a reference input signal and an output signal, loop filters for filtering the phase difference signal, and an oscillator controlled by the filtered phase difference signal for generating the output signal, wherein an adapting circuit is provided for reducing the settling time at switch-on of the phase-locked loop, which adapting circuit correlates the actual switch-on of the phase-locked loop with the signal behavior of the reference input signal.

A transceiver circuit of a tire pressure monitoring system is also provided, having a device for generating and/or synchronizing a clock signal, the device having an inventive phase-locked loop in order to set up short-term data communication with another transceiver circuit of the same tire pressure monitoring system during operation.

The present invention is based on the knowledge that the phase error and thus the settling time depends significantly on the point in time relative to a reference input signal at which the phase-locked loop is switched on or reset. The concept of the present invention includes correlating the switch-on or resetting of the phase-locked loop with the signal behavior of the reference input signal.

In this connection, correlation means that the actual switch-on of the phase-locked loop in the presence of a switch-on signal is performed at a fixed, predetermined point in time of the reference input signal in each case. This fixed, predetermined point in time can be derived from the signal behavior of the reference signal, for example.

Actual switch-on is understood to mean that despite the presence of a switch-on signal (for example, an enable or reset signal) meant to indicate a switch-on or reset of the phase-locked loop, the phase-locked loop is not switched on until the fixed, predetermined point in time of the reference input signal is simultaneously passed. Thus, the switch-on or reset signal alone is not sufficient for actual switch-on of the phase-locked loop. Instead, two switch-on conditions are necessary, which is to say the presence of a switch-on or reset signal on the one hand, and the presence of the fixed, predetermined point in time in the signal behavior of the reference input signal on the other hand.

A defined signal transition specified in advance, for example the falling and/or rising edge of the reference input signal, is employed as the fixed, predefined point in time. This ensures that the phase-locked loop is switched on at exactly the point in time at which the reference signal also has a signal transition, so that the phase-locked loop already has a minimal phase difference, even ideally no phase difference, when settling.

Since the phase-locked loop thus only has to regulate out a very small phase difference, it is already locked-in after an extremely short time, with the overall result of a minimal settling time. This provides the advantage, particularly in an application for a tire pressure monitoring system, that a longer period of time is available for the actual data communication, since the phase-locked loop requires a minimal period of time to settle the phase-locked loop.

In an embodiment, the adapting circuit provides at its output a first control signal by which, when the phase-locked loop is switched on, the oscillator is not switched in at least until there is a signal transition of the reference input signal. This first control signal thus controls the actual switch-on of the phase-locked loop, and thus controls the correlation between the presence of a first switch-on condition (reset, enable) and the presence of a second switch-on condition (predefined point in time), hence a signal transition of the reference input signal.

In an embodiment, the adapting circuit contains a first input for coupling in the reference input signal and a second input for coupling in a switch-on signal. The enable signal or a reset signal functions as the switch-on signal, for example. The signal transition here can, for example, be a falling or rising signal edge of the reference input signal, wherein preferably a signal transition is used that corresponds to the matching signal transition of the switch-on signal, which is to say that in the case of a rising edge of the switch-on signal a rising edge of the reference input signal should also be used. This switch-on signal puts the phase-locked loop into a state in which it can be switched on by a first control signal. The adapting circuit now combines the reference input signal with the switch-on signal and generates therefrom the first control signal that switches the phase-locked loop on, wherein this first control signal can be obtained at an output of the adapting circuit.

In an embodiment, the adapting circuit has at least one latch that serves to provide the first control signal. This latch can be designed as a flip-flop, which thus stores the applicable states or logic level of the reference input signal and of the switch-on signal. Preferably an RS flip-flop or a DQ flip-flop is used here. Other embodiments of the adapting circuit would also be possible, however, even though the use of a flip-flop or a conventional latch represents a very simple implementation of the adapting circuit in terms of circuit design.

In another embodiment, a feedback path is provided, through which a feedback signal derived from the output signal by dividing down with a predefined or adjustable division factor can be fed back into an input of the phase comparator circuit. A (frequency) divider or even a frequency multiplier is typically located in the feedback path.

According to an embodiment of the inventive adapting circuit, at least the oscillator can have a control input through which the first control signal can be coupled into the oscillator and by which, when the phase-locked loop is switched on, it is not switched in until a signal transition of the reference input signal occurs. An enable input or a reset input, for example, may be provided as input. The oscillator is switched on through this switch-on signal and immediately generates, which is to say without settling, a suitable oscillator output signal. This oscillator output signal constitutes, as it were, the output signal of the phase-locked loop and is supplied to the phase detector through the feedback path. Typically an oscillator has no lock-in time at all, and hence no settling time at all. However, a maximum of one period is lost here, since the output signal provided by the oscillator requires one clock period to reach the input of the phase comparator circuit through the feedback path. Nonetheless, a difference signal is produced at the output of the phase detector, said signal already reflecting a more or less minimal phase difference.

In a further embodiment, the phase comparator and/or the divider as well as the oscillator also can have a control input for coupling in the control signal. In this way, the control signal can be supplied to the phase comparator and the divider as well as to the oscillator, thus avoiding the above-described time loss of one clock and implementing a phase difference signal with minimal phase difference at the output of the phase comparator immediately upon switch-on or provision of the control signal.

In an embodiment, the oscillator is designed as a voltage-controlled oscillator (VCO). However, it would also be possible here to use a current-controlled oscillator (ICO), even though a voltage-controlled oscillator is preferable for energy reasons, especially in a tire pressure monitoring system.

In an embodiment, the loop filter is designed as a low-pass filter. Preferably, the loop filter has as small a bandwidth as possible, in the range up to 125 kHz. This is advantageous with regard to reducing the noise of the loop filter, since a small bandwidth of the loop filter is also associated with a small noise signal at the output of the loop filter. Typically, the loop filter is implemented as an analog loop filter, even though a digital implementation of the loop filter is also possible in principle, despite the fact that it is more complex in terms of circuit design.

In an embodiment, the phase comparator can be designed as a phase detector. It is also possible, especially in applications in tire pressure monitoring systems, for the phase comparator to be designed as a phase/frequency detector. In the case of a phase detector, it has, in the simplest embodiment, controllable current sources connected in series with one another, each of which is driven by control signals of different polarity. The tap between the two current sources also forms the output of the phase/frequency detector. The two current sources of the phase/frequency detector are ideally dimensioned with equal size, although this is never entirely the case on account of manufacturing tolerances. Particularly for these reasons, it is advantageous for the phase/frequency detector to also be supplied with the control signal during switch-on of the phase-locked loop.

In an embodiment, at least one charge pump is arranged between the phase comparator and the loop filter. To this end, it is advantageous for a charge pump control circuit to be provided, which, as specified by a second control signal, produces a third control signal for driving at least one charge pump. The second control signal indicates in this regard whether the phase-locked loop is closed or not.

In another embodiment, at least two charge pumps are provided, wherein the first charge pump produces a smaller charge pump current than the second charge pump. Preferably, a maximum of one of the two charge pumps, and in particular exactly one charge pump, is activated in this context. The first charge pump here can be activated through the third control signal if the phase-locked loop is locked in. Additionally or alternatively, the second charge pump can be activated through the third control signal if the phase-locked loop is not locked in.

Further, at least two phase comparators can be provided, wherein the first phase comparator is designed as a phase detector and the second phase comparator is designed as a phase/frequency detector. In a preferred further development, the first charge pump follows the output of the phase detector and the second charge pump follows the output of the phase/frequency detector.

An embodiment also provides what is known as a closed loop detection circuit, which detects whether or not the phase-locked loop is closed.

In one embodiment, the divider is designed as a ¼ divider, and is thus designed to divide the output signal of the phase-locked loop, and thereby in particular its frequency and/or phase, by four.

In another embodiment of the invention, a lock detection circuit is provided that is designed to detect whether or not the phase-locked loop is locked in. In the case of a phase-locked loop that is locked in, the lock detection circuit generates a lock control signal. In the case of a phase-locked loop that is not locked in, the lock detection circuit generates a lock control signal that is inverted with respect thereto.

In an embodiment of the inventive transceiver circuit, the circuit is a component of a transponder or is designed as a transponder. In addition, this transceiver circuit can be applied to a rim of a motor vehicle wheel.

In another embodiment of the invention, the transponder is vulcanized into a material of a tire, for example into its rubber material.

Further scope of applicability of the present invention will become apparent from the detailed description given hereinafter. However, it should be understood that the detailed description and specific examples, while indicating preferred embodiments of the invention, are given by way of illustration only, since various changes and modifications within the spirit and scope of the invention will become apparent to those skilled in the art from this detailed description.

### BRIEF DESCRIPTION OF THE DRAWINGS

The present invention will become more fully understood from the detailed description given hereinbelow and the accompanying drawings which are given by way of illustration only, and thus, are not limitive of the present invention, and wherein:

FIG. 1 illustrates a first, general embodiment of a phase-locked loop;

FIG. 2 illustrates a second embodiment of a phase-locked loop;

FIG. 3 shows signal vs. time diagrams illustrating the functionality of the phase-locked loop from FIG. 2 during a settling process;

FIG. 4 illustrates a third embodiment of an inventive phase-locked loop;

FIG. 5 shows signal vs. time diagrams illustrating the functionality of the phase-locked loop from FIG. 4 during a settling process;

FIG. 6 illustrates a fourth embodiment of an inventive phase-locked loop;

FIG. 7 is a block diagram illustrating a tire pressure monitoring system with a transponder containing an inventive phase-locked loop;

FIG. 8 illustrates a conventional phase-locked loop, known from the aforementioned technical book by Tietze and Schenk, for example; and

FIG. 9 shows signal vs. time diagrams illustrating the functionality of the prior art phase-locked loop from FIG. 8 during a settling process.

### DETAILED DESCRIPTION

In the drawings, like or functionally like elements and signals are identified with the same reference labels, unless otherwise specified.

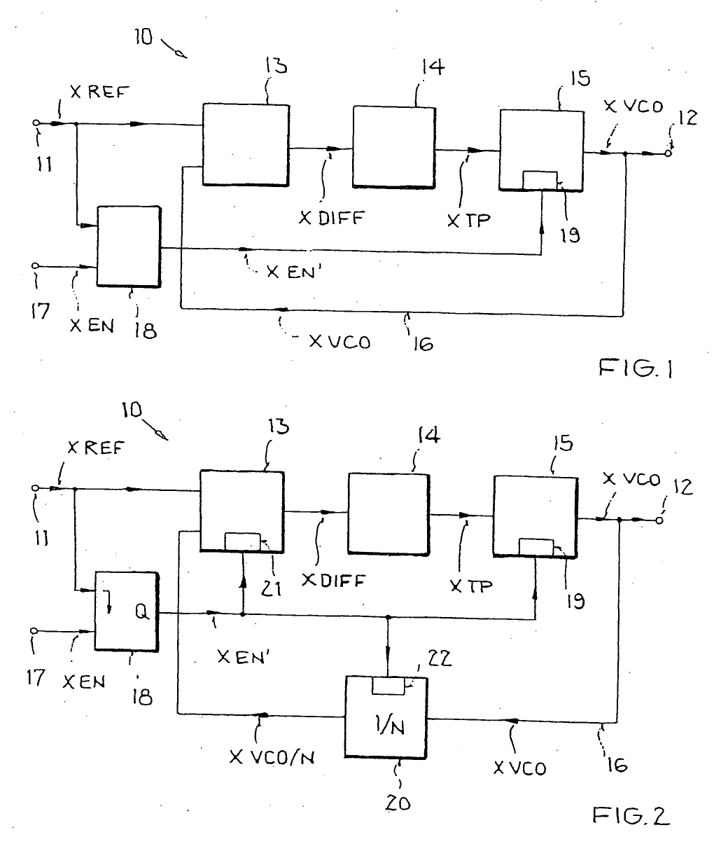

FIG. 1 shows a block diagram of an embodiment of a phase-locked loop. The phase-locked loop 10 is labeled with the reference symbol 10 here. The phase-locked loop has a reference input 11 into which a reference input signal XREF can be coupled, and an output from which an output signal XVCO can be obtained. Arranged one after the other in series between the input 11 and the output 12 are a phase comparator 13, a loop filter 14, and an oscillator 15. In addition, a feedback path 16 is provided through which the output signal XVCO can be obtained and coupled into an input of the phase comparator 13.

The phase-locked loop 10 also has another input 17, through which, e.g., a digital switch-on signal XEN can be coupled in. Moreover, a control unit 18 is provided that has two inputs and one output. Each input of the control unit 18 is connected to one of the inputs 11, 17. A modified switch-on signal XEN′ is provided at the output of the control unit 18. In FIG. 1, this signal is coupled into a control input 19 of the oscillator 15.

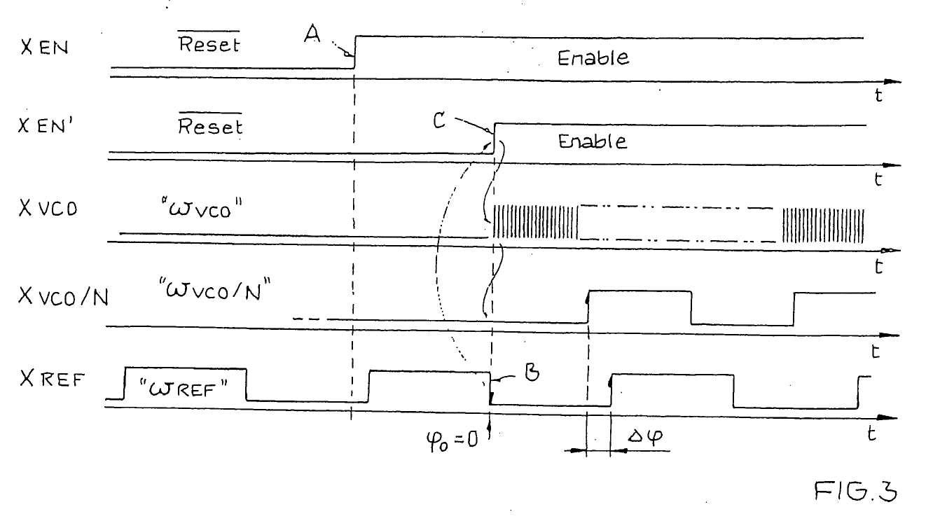

FIG. 2 shows a second example embodiment of a phase-locked loop, expanded relative to FIG. 1. The phase-locked loop 10 is designed as a digital phase-locked loop 10.

In contrast to the example embodiment in FIG. 1, the phase comparator 13 here is designed as a phase/frequency detector 13. The loop filter 14 (LF=loop filter) here is designed as a narrow-band low-pass filter. The oscillator 15 is designed as a voltage-controlled oscillator 15.

In addition, a frequency divider 20 is provided in the feedback path 16. The frequency divider 20 is designed to multiply the frequency of the output signal XVCO by a division factor 1/N, so that the divided-down output signal XVCO/N is provided at the output of the frequency divider 20. The divider 20 contains, in particular, a counter, for example an up-counter, that continuously counts the clocks generated at the output of the oscillator 15 and generates a signal transition of the clock signal XVCO/N for a predetermined number of clocks.

The control unit 18 here is designed as a flip-flop. The flip-flop 18 is capable of changing its state at a falling edge of the reference input signal XREF. In contrast to the example embodiment in FIG. 1, the phase/frequency detector 13 and the divider 20 here also have a control input 21, 22. The switch-on signal XEN′ that is provided by the control unit 18 is coupled into all control inputs 19, 21, 22.

The operation of the phase-locked loop according to FIG. 2 is described below in detail, specifically with reference to the signal vs. time diagrams in FIG. 3.

In the switched on and locked in state of the phase-locked loop 10, the oscillator 15 continuously generates an oscillator output signal XVCO at the frequency ωVCO, which is available at the output 12. This output signal XVCO is fed through a divider 20 as the clock signal XVCO/N with the frequency ωVCO/N to an input of the phase/frequency detector 13. In addition, a reference input signal XREF with the frequency ωREF is supplied to the phase/frequency detector 13 through the reference input 11. The phase/frequency detector 13 compares the two signals XREF, XVCO/N to one another and generates a difference signal XDIFF on the output side. The difference signal XDIFF is a function of the phase error of the phases of the reference input signal XREF and clock signal XVCO/N. This difference signal XDIFF is supplied through a driver circuit, which is not shown in FIG. 2 and which, for example, is part of the phase/frequency detector 13, to a following low-pass filter 14, which produces therefrom a low-pass filtered reference signal XTP on the output side. This low-pass filtered reference signal XTP, which still remains a function of the phase difference, serves to drive the voltage-controlled oscillator 15, or in other words, the oscillator 15 is driven in accordance with the determined phase difference, so that the frequency of the oscillator 15 is changed in accordance with the phase difference.

In the switched off or reset state of the phase-locked loop 10, its elements, which is to say the phase/frequency detector 13, the loop filter 14, the oscillator 15, and the divider 20, are inactive. In this state, a signal XEN in the form of a reset (“0”) is supplied to the control unit 18. If the phase-locked loop 10 should now be switched on, then this signal changes its logic level (“1”), which should signal a switch-on (enable) (signal transition A). The reference input signal XREF is supplied to the control device 18 through the second input. In the example in FIG. 3, which is to say at the signal transition A of the signal XEN, this signal has a low logic level (“0”). Consequently, the control signal XEN′ at first remains at a low logic level (“0”), which means that the elements of the phase-locked loop 10 still remain deactivated. At a signal change in the reference signal from a low (“0”) to a high logic level (“1”), as well, the control signal XEN′ at first remains at the low logic level (“0”). Now, the flip-flop 18 is designed such that a signal transition C of the control signal XEN′ takes place only at the same time as a signal transition B of the reference input signal XREF from a high logic level (“1”) to a low logic level (“0”) occurs, which is to say a falling clock edge. In FIG. 2, this is indicated by a downward arrow at the data input of the flip-flop 18. The phase/frequency detector 13, the oscillator 15, and the divider 20 are now activated through the control signal XEN′ or its high logic level (“1”), which causes the oscillator 15, in particular, to immediately provide the clock signal XVCO on the output side, which is to say without settling. As a result of the fact that the oscillator 15 starts to clock more or less simultaneously with the points in time of the signal transitions B, C, essentially no initial phase φ0 arises here. The following thus applies:
φ_{O}≈0 (7)

Taken together with equations (2)-(4) above, the following then applies:
Δφ≈∫ω_{REF}dt−∫ω_{VCO}dt (8)
and hence:
   Δφ≈φ_{REF}−φ_{VCO} (9).

From equation (9) and FIG. 3, it is evident that the phase error Δφ is minimal according to the invention, and in the event that φ_{REF}=φ_{VCO} is in fact equal to zero (Δφ=0), the ideal case. This means that the phase-locked loop 10 transitions to the locked-in state immediately after it is switched on.

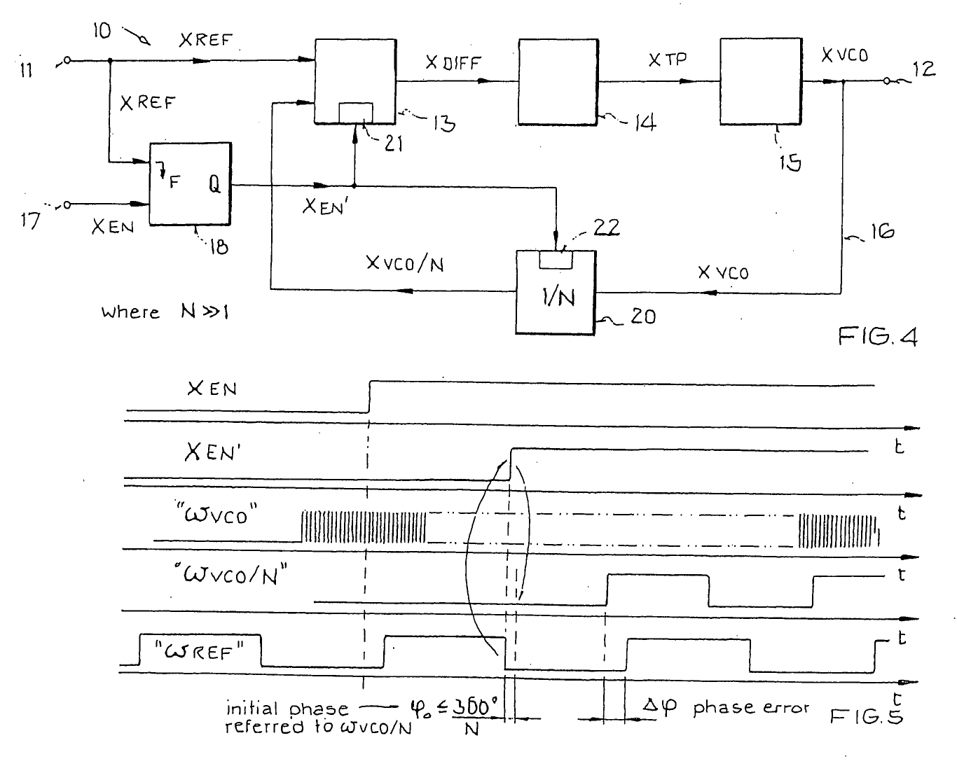

FIG. 4 shows a third embodiment of an inventive phase-locked loop. FIG. 5 shows the corresponding signal vs. time diagrams to illustrate how the phase-locked loop from FIG. 4 functions during a settling process.

Unlike the exemplary embodiment in FIG. 2, no connecting line is provided from the flip-flop 18 to the oscillator 15 in the phase-locked loop 10 in FIG. 4, so as a result the oscillator 15 is not driven by the control signal XEN′. This variant is especially advantageous for applications in which the division coefficient N is very much larger than one (N>>1). Typical values for the division coefficient N lie in the range from 20 to 100, preferably at about N≈50.

While the phase-locked loops 10 in FIGS. 1 and 2 relate primarily to static applications, the phase-locked loop shown in FIG. 4 is also suited to a dynamic application of the PLL circuit 10. Especially in transponders that are used in a very dynamic environment, hence one in which the reference signal XREF is subject to very rapid changes, this application is especially advantageous. Such changes result, for example, when the reference signal XREF repeatedly disappears, or at least becomes significantly weaker. If the quality, and thus the signal amplitude, of the reference signal XREF becomes very bad or even incorrect as a result of the very dynamic environment, it is frequently necessary to disconnect the difference signal XDIFF at the output of the phase/frequency detector 13 and thus break the connection between the phase/frequency detector 13 and the loop filter 14. This is intended to interrupt the function of the phase-locked loop 10 in order to prevent the oscillator 15 from following the “bad” or incorrect reference signal XREF.

In spite of an interrupted difference signal XDIFF, it can happen that the oscillator 15 (unintentionally) continues to operate for a certain period of time. This results from the circumstance that the input of the oscillator 15 is connected to the output of the loop filter 14, whose RC low-pass element is able to store charge over a relatively long period of time due to the low leakage currents in the loop filter 14. The resulting voltage then functions as the input voltage for the voltage-controlled oscillator 15 that follows; in the absence of additional measures—as is the case in the examples in FIGS. 1 and 2—the voltage-controlled oscillator 15 now attempts to generate an output signal derived from this stored voltage signal. This is undesired.

The circuit in FIG. 5 prevents this. To this end, the quality of the reference signal XREF is monitored by a special monitoring arrangement. If the monitored quality is bad or if no reference signal XREF is present, the phase comparator 13 is deactivated via the control signal XEN′, thus interrupting the difference signal XDIFF. As soon as the quality of the reference signal XREF is again adequate, the phase-locked loop 10 can be closed again, for example by switching the phase comparator 13 on through the control signal XEN′. In any case, as a result of the interruption a relatively small initial phase φ₀ is obtained. However, the initial phase φ₀ is (significantly) smaller than 360°/N, so that the phase error Δφ is minimized as much as possible. This results from the fact that the oscillator 15 cannot be synchronized, since its frequency must be as uniform as possible. However, the divider 20 and the phase comparator 13 can be synchronized by means of the control signal XEN′.

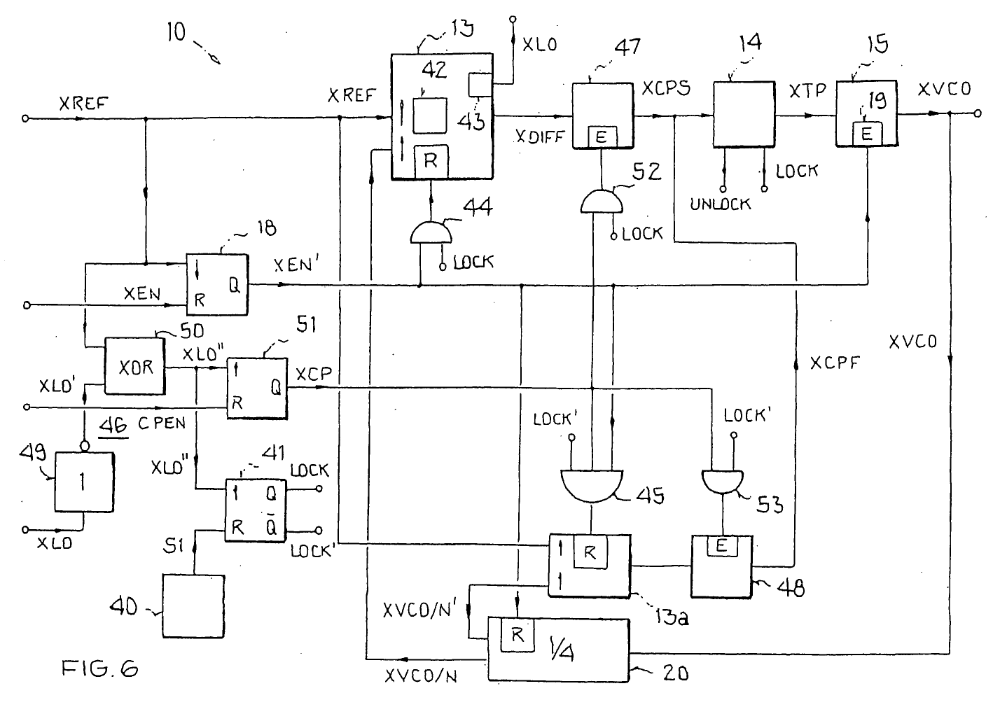

FIG. 6 shows a fourth example embodiment of the inventive phase-locked loop. In the example embodiment in FIG. 6, all of the reference symbols marked with “a” are assigned to the elements in the path in which the phase/frequency detector 13a is arranged. In FIG. 6, each upward-pointing arrow at an input of a circuit element is intended to indicate that this signal is triggered at a rising edge of the corresponding signal that is coupled in. In a similar manner, a downward-pointing arrow designates that the relevant circuit element is triggered by the falling edge of the corresponding signal that is coupled in. The inputs of a given circuit element that are labeled with E indicate enable inputs by means of which the circuit element can be switched on. The inputs labeled with R indicate reset inputs by means of which the relevant circuit elements can be reset.

In the example embodiment in FIG. 6, both a phase comparator designed as a phase detector 13 and a phase comparator designed as a phase/frequency detector 13a are provided. These two phase comparators 13, 13a work largely independently of one another, wherein the phase detector is primarily active in the case of a locked-in phase-locked loop, and the phase/frequency detector is primarily active in the case of a phase-locked loop that is not yet locked in. This is described below in detail.

The phase-locked loop 10 also contains a lock detector labeled 40 which detects whether the frequency of the reference input signal XREF is locked in or not. If the frequency is not yet locked in, the frequency detector 40 outputs a control signal S1 that indicates that the phase-locked loop 10 is not yet locked in. This control signal S1 is fed to the reset input R of a subsequent lock detection circuit 41, by which means the latter is reset. This lock detection circuit 41 generates, at its output, status signals LOCK, LOCK′, wherein the status signal LOCK indicates that the phase-locked loop 10 is locked in, while the status signal LOCK′ conversely indicates that the phase-locked loop 10 is not in a locked in state. In the present example embodiment, the lock detection circuit 41 is designed as a DQ flip-flop 41. The flip-flop 41 here is triggered by the rising edge of a status signal XLO″ that contains information on whether the phase-locked loop 10 is closed. The status signal LOCK can be obtained at the data output of the flip-flop 41, and the status signal LOCK′ can be obtained at the inverted output Q′ of the flip-flop 41.

The phase detector 13 also has a device 42 designed to detect whether the phase-locked loop 10 is closed. This device 42 is also designated as a closed loop detection circuit. If the phase-locked loop 10 is closed, the device 42 outputs a control signal XLO, which indicates a closed phase-locked loop 10. This control signal XLO can be tapped at a control output 43 of the phase detector 13. The device 42 determines this information from the phase position of the reference input signal XREF and the output signal XVCO/N that has been divided down by the divider 20. Preferably the divider 20 is designed as a ¼ divider for this purpose, which thus divides the output signal XVCO, or its frequency or phase, by four. This quartered output signal XVCO is compared to the 0° phase and the 180° phase of the reference input signal XREF. The desired information as to whether the phase-locked loop 10 is closed can be obtained from this comparison.

The reference input signal XREF and the divided-down output signal XVCO/N′ are supplied to the input of the phase/frequency detector 13a—in similar fashion to the phase detector 13—wherein each of these is triggered in the phase reference detector 13a at their rising signal edges.

The phase detector 13 also has a reset input 21, by which means the phase detector 13 can be reset. An AND gate 44 is provided for the purpose of obtaining the corresponding reset signal; the status signal LOCK and the control signal XEN′ are each supplied to said gate.

In like manner, a reset signal can also be supplied to the phase/frequency detector 13a, at its reset input 21a. This reset signal is generated by AND operations of the status signal LOCK′, the control signal XEN′, and a control signal XCP in an AND gate 45.

The control signal XCP signals whether or which of the charge pumps 47, 48—described in greater detail below—will be driven. The control signal XCP is generated in a charge pump control circuit 46 provided especially for this purpose. The charge pump control circuit contains an inverter 49, an XOR gate 50 following the output of the inverter 49, and a DQ flip-flop 51 connected after said gate.

The inverter 49 inverts the control signal XLO of the phase detector 13, which indicates that the phase-locked loop 10 is closed, and thus not interrupted. The control signal XLO′ thus inverted is combined with the reference input signal XREF in an XOR operation in the following XOR gate, resulting in a corresponding status signal XLO″. The status signal XLO″ is supplied to the data inputs of the DQ flip-flop 41 and of the DQ flip-flop 51. In the reset input R of the DQ flip-flop 51, the control signal CPEN is coupled in, which signal can thus be used to reset the DQ flip-flop 51. This control signal CPEN indicates whether at least one of the two charge pumps 47, 48 should be activated. At its output side, the DQ flip-flop 51 outputs the control signal XCP for driving the charge pumps 47, 48, the phase detector 13, and the phase frequency detector 13a.

As already described above, the phase-locked loop 10 has two charge pumps 47, 48. One of these charge pumps 47 is connected after the output side of the phase detector 13, whereas the other charge pump 48 follows the output of the phase frequency detector 13a. The charge pump 47 is designed as a “slow” charge pump 47, and thus produces at its output a relatively low charge pump current XCPS. This slow charge pump 47 is intended for the locked-in state of the phase-locked loop 10.

In contrast to the charge pump 47, the charge pump 48 following the output of the phase frequency detector 13a is significantly faster, and therefore is designed to provide a comparatively high charge pump current XCPF at its output. This charge pump 48 serves the purpose of providing a comparatively high charge pump current XCPF when the phase-locked loop 10 is in the not-locked state in order to lock in the phase-locked loop 10 again as quickly as possible, or at least faster than would be possible with the charge pump 47. This capability is not required in the not-locked state [sic], so the charge pump 47 can provide a comparatively low current XCPS in the locked-in state.

In this context, no more than one of the two charge pumps 47, 48 is activated. To this end, an AND gate 53 is associated with each of the charge pumps 47, 48. The control signal XCP is supplied to the gate in each case. In the case of the AND gate 52 for the slow charge pump 47, this control signal XCP is combined in an AND operation with the status signal LOCK; in contrast, the control signal XCP is combined in an AND operation with the inverted control signal LOCK′ in the case of the AND gate 52 for the fast charge pump 48. Consequently, (at most) only one of these charge pumps 47, 48 supplies a charge pump current CXPS, CXPF at the output side, which is then supplied to the following loop filter 14 in each case.

The loop filter 14 likewise receives the status signals LOCK, LOCK′ through appropriate control inputs, and thus information as to whether or not the phase-locked loop 10 is now locked in.

The control signal XCP is additionally coupled into a hold input of the phase detector 13. This achieves the result that, if the control signal XCP is present, which is to say in the case that at least one of the charge pumps 47, 48 should be switched on, the phase detector 13 is not reset, but instead its operation is maintained. This is very important to the mode of operation of the inventive phase-locked loop 10, and especially for its fast lock-in.

The embodiment in FIG. 6 is distinguished in particular by the fact that extraordinarily fast lock-in of the phase-locked loop 10 is ensured, because it monitors, firstly, whether the phase-locked loop 10 is already locked in, and secondly, whether the phase-locked loop 10 is closed. Depending on this information and on the combination of the reference input signal XREF with the divided-down output signal XVCO/N, either the fast or the slow charge pump 47, 48 can be activated, thus significantly shortening the time until the phase-locked loop 10 is locked in again.

This makes it possible to provide phase-locked loops 10 for very high frequencies, for example for frequencies of 1.00 MHz and above, in particular of 500 MHz and above. This method is also especially well-suited to use in transponders which carry out data communication on the basis of PSK modulation, such as is the case in tire pressure monitoring systems, for example.

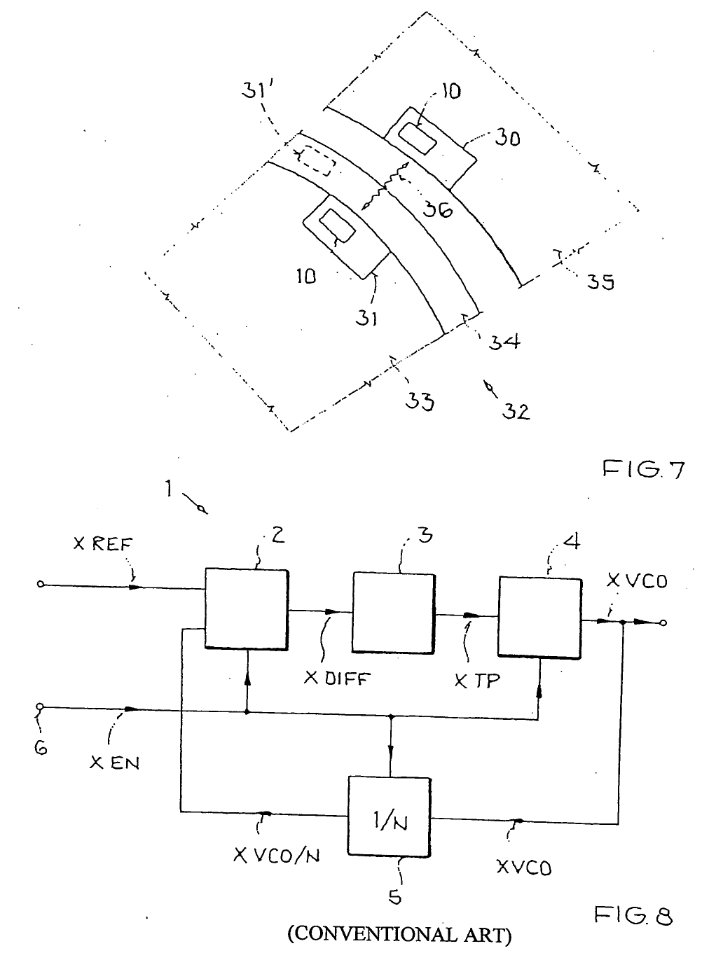

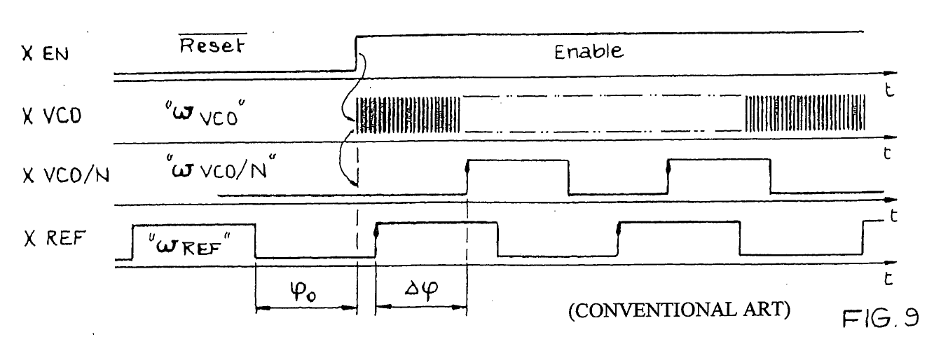

FIG. 7 uses a block diagram to show a section of a tire pressure monitoring system in a motor vehicle, with the motor vehicle being only schematically indicated. The tire pressure monitoring system includes a transceiver circuit 30 on the body side, and a transponder 31 on the wheel side. The wheel 32, which is only shown in part, includes a rim 33 and a tire 34. In the present exemplary embodiment, the transponder 31 is affixed to an outside (edge) of the wheel rim 33. The body-side transceiver circuit 30 is affixed to a body part 35 in the vicinity of the wheel well. The transponder 31 is in a data communications connection with the transceiver circuit 30, which is indicated by the arrow 36. The transponder 31 has the phase-locked loop 10. In addition or alternatively thereto, the transceiver circuit 30 can also have such a phase-locked loop 10.

In addition or alternatively, it would also be possible for the transponder 31′ to be located inside the tire 34, for example in that the transponder 31′ is vulcanized into the (rubber) material of the tire 34. It is preferable in this context for the transponder 31′ to be located as far as possible from the rim 33, which is advantageous with regard to optimum data communications, in particular. This variant of the placement of the transponder 31′ is shown in dashed lines in FIG. 7.

Although the present invention was described above on the basis of a preferred example embodiment, it is not limited thereto, but can rather be modified in many diverse ways.

Thus, the inventive phase-locked loop is not necessarily designed for a transponder or transceiver circuit in a tire pressure monitoring system, but rather can be used in any desired applications that require, in particular, as short a settling time as possible. Such applications may occur, for example, in telecommunications in the case of frequency hopping, in which different frequencies are used for data communication, and it is necessary for this purpose to switch from one frequency to another very quickly.

Nor is the invention limited to the example embodiments and applications of a phase-locked loop shown in FIGS. 1, 2, 4, 6, 7, but rather can be modified in many ways and also used elsewhere. Thus, the phase comparator can also take the form of a phase detector, the oscillator can also take the form of a current-controlled oscillator, and the loop filter can also take the form of a bandpass filter or all-pass filter. Furthermore, the embodiment of the control unit as a flip-flop represents a design version that is very simple in terms of circuit design, but is not compulsory. Instead, rather, this can also be replaced by any desired control unit, which can be, for example, part of a software-controlled unit, such as a microprocessor, or a hard-wired logic circuit (for example, FPGA, PLD).

The invention being thus described, it will be obvious that the same may be varied in many ways. Such variations are not to be regarded as a departure from the spirit and scope of the invention, and all such modifications as would be obvious to one skilled in the art are to be included within the scope of the following claims.

What is claimed is:

1. A phase-locked loop having a reduced settling time for a transceiver circuit of a tire pressure monitoring system, the phase-locked loop comprising:
a phase comparator for generating a phase difference signal by comparing a reference input signal with an output signal;
a loop filter for filtering the phase difference signal;
an oscillator controlled by the filtered phase difference signal for generating the output signal; and
an adapting circuit for reducing the settling time at switch-on of the phase-locked loop, the adapting circuit correlating the actual switch-on of the phase-locked loop with the signal behavior of the reference input signal,
wherein the phase comparator, the loop filter, the oscillator and the adapting circuit are sequentially arranged in a signal path.

2. The phase-locked loop according to claim 1, wherein the adapting circuit provides at its output a first control signal by which, when the phase-locked loop is switched on, the oscillator is not switched in at least until there is a signal transition of the reference input signal.

3. The phase-locked loop according to claim 1, wherein the adapting circuit has a first input for coupling in the reference input signal and a second input for coupling in a switch-on signal, which puts the phase-locked loop into a state in which it can be switched on by a first control signal, and wherein the adapting circuit combines the reference input signal with the switch-on signal and generates therefrom the first control signal that switches on the phase-locked loop.

4. The phase-locked loop according to claim 3, wherein the adapting circuit has a latch or a flip-flop for providing the first control signal.

5. The phase-locked loop according to claim 1, wherein a feedback path with a divider located therein is provided, through which a feedback signal derived from the output signal by dividing down with a division factor (1/N) can be fed back into an input of the phase comparator.

6. The phase-locked loop according to claim 1, wherein the oscillator and/or the phase comparator and/or the divider has a control input for coupling in the first control signal through which the oscillator and/or the phase comparator and/or the divider, when the phase-locked loop is switched on, is switched in only at such time as a signal transition of the reference input signal occurs.

7. The phase-locked loop according to claim 1, wherein the oscillator is a voltage-controlled oscillator.

8. The phase-locked loop according to claim 1, wherein the loop filter is a low-pass filter.

9. The phase-locked loop according to claim 1, wherein the loop filter has a small bandwidth in a range up to 125 kHz.

10. The phase-locked loop according to claim 1, wherein the phase comparator is a phase detector or a phase/frequency detector.

11. The phase-locked loop according to claim 1, wherein at least one charge pump is arranged between the phase comparator and the loop filter.

12. The phase-locked loop according to claim 11, wherein a charge pump control circuit is provided, which, as specified by a second control signal that indicates whether the phase-locked loop is closed, produces a third control signal for driving the at least one charge pump.

13. The phase-locked loop according to claim 11, wherein at least two charge pumps are provided, wherein the first charge pump produces a smaller charge pump current than the second charge pump.

14. The phase-locked loop according to claim 13, wherein a maximum of one of the two charge pumps is activated, and the first charge pump is activated through a third control signal if the phase-locked loop is locked in, and/or the second charge pump is activated through the third control signal if the phase-locked loop is not locked in.

15. The phase-locked loop according to claim 1, wherein at least two phase comparators are provided, and wherein the first phase comparator is a phase detector and the second phase comparator is a phase/frequency detector.

16. The phase-locked loop according to claim 13, wherein the first charge pump follows the output of the phase detector and the second charge pump follows the output of the phase/frequency detector.

17. The phase-locked loop according to claim 1, wherein a closed loop detection circuit is provided, which detects whether the phase-locked loop is closed.

18. The phase-locked loop according to claim 5, wherein the divider divides the frequency and/or phase of the output signal by four.

19. The phase-locked loop according to claim 1, wherein a lock detection circuit is provided that detects whether the phase-locked loop is locked in, and which, in the case of a locked-in phase-locked loop, generates a lock control signal, and in the case of a phase-locked loop that is not locked in, generates a lock control signal that is inverted.

20. A transceiver circuit of a tire pressure monitoring system, the circuit comprising:
a device for generating and/or synchronizing a clock signal; and
a phase-locked loop in order to set up short-term data communication with another transceiver circuit of the same tire pressure monitoring system during operation thereof,
wherein the phase-locked loop comprises:
a phase comparator for generating a phase difference signal by comparing a reference input signal with an output signal;
a loop-filter for filtering the phase difference signal;
an oscillator controlled by the filtered phase difference signal for generating the output signal; and
an adapting circuit for reducing the settling time at switch-on of the phase-locked loop, the adapting circuit correlating the actual switch-on of the phase-locked loop with the signal behavior of the reference input signal,
wherein the phase comparator, the loop filter, the oscillator and the adapting circuit are sequentially arranged in a signal path.

21. The transceiver circuit according to claim 20, wherein the transceiver circuit is a transponder and is applied to a rim of a motor vehicle wheel.

22. The transceiver circuit according to claim 21, wherein the transponder is vulcanized into a rubber material of a tire of the wheel.
